(19) United States
(12) Patent Application Publication
(10) Pub. No.: US 2013/0299384 A1
(43) Pub. Date: Nov. 14, 2013

(54) FRONT OPENING WAFER CONTAINER WITH WAFER CUSHION

(71) Applicant: Matthew A. Fuller, Colorado Springs, CO (US)

(72) Inventor: Matthew A. Fuller, Colorado Springs, CO (US)

(73) Assignee: ENTEGRIS, INC., Billerica, MA (US)

(21) Appl. No.: 13/880,711

(22) PCT Filed: Oct. 19, 2011
(86) PCT No.: PCT/US11/56917

§ 371 Date: Jun. 24, 2013

Related U.S. Application Data
(60) Provisional application No. 61/394,633, filed on Oct. 19, 2010.

(51) Int. Cl. H01L 21/673

(52) U.S. Cl. CPC H01L 21/67386
USPC 206/711; 53/485; 53/471

(57) ABSTRACT

A front opening wafer container suitable for 450 mm wafers utilizes a wafer cushion on the front door with varying inclinations on the inside surface of a lower leg of V-shaped wafer cushion engagement portions on the door. Such provides enhanced performance. More specifically, in an embodiment of the invention, a front opening wafer container has, in cross section, horizontal V-shaped groove with the inside surface of the lower leg of the V having with at least two surface portions with different inclinations from horizontal. The surface portion adjacent the apex, where the edge of the wafer seats, having a lesser inclination from horizontal than a surface portion more distal from apex.

### RELATED APPLICATIONS

The present application is a National Phase entry of PCT Application No. PCT/US2011/056917, filed Oct. 19, 2011, which claims priority to U.S. Provisional Application Ser. No. 61/394,633, filed Oct. 19, 2010, the disclosures of which are hereby incorporated by reference herein in their entirety.

### BACKGROUND OF THE INVENTION

Integrated circuits such as computer chips are manufactured from silicon wafers. The silicon wafers need to be maintained in extremely clean and contamination free environments during their transport and in between manufacturing process steps. Additional, required or desirable characteristics of containers to transport and/or store semiconductor wafers include light weight, rigidity, cleanliness, limited gaseous emissions, and cost effective manufacturability. The containers provide hermetic or close to hermetic isolation of wafers when the containers are closed. Simply stated, such containers need to keep the wafers clean, uncontaminated, and undamaged.

Plastic containers have been used for decades for transporting and storing wafers in-between process steps. Selected polymer materials provide adequate characteristics. Such containers have highly controlled tolerances for interfacing with processing equipment as well as the equipment/robots that transport the containers.

Driven by cost efficiencies and improved manufacturing capabilities, the size of wafers utilized in manufacturing semiconductors has been increasing. Now several fabrication facilities utilize 300 mm wafers. Front opening wafer containers have become the industry standard for transporting and storing large diameter 300 mm wafers.

In such wafer containers, the front door is latchable to a container portion and closes a front access opening through which the wafers are robotically inserted and removed. When the container is fully loaded with wafers the door is inserted into the door frame of the container portion and latched thereto. In such a configuration the wafers have a first horizontal seating position on the laterally placed shelves and then, upon insertion of the door, the wafers are vertically elevated to a second seating position by wafer supports with angled ramps at the rear of the wafer container as well as wafer supports, often referred to as “cushions”, on the inside surface of the door. See U.S. Pat. Nos. 6,267,245 and 6,010,008 which are owned by the owner of the present application and which are hereby incorporated by reference. The angled ramps are part of V-shaped grooves, with the V rotated 90 degrees, whereby the lower leg of the V engages the wafer edge and rides up the inclination of the lower leg as the door is being inserted, ultimately seating at the inside apex of the V-shaped groove. When seated the cushions on the door then provide upward, downward, and inward constraint.

A problem discovered in fabricating front opening plastic containers for holding and/or transporting larger wafers, for example 300 mm containers, is that the expanses of plastic utilized on the top, bottom, sides, front, and back of the container may flex due to the increased weight of the wafer load. Particularly, when the container is picked up by the robotic flange affixed to the top of the container. The flexing can compromise the sealing of the door to door frame by distorting the shape of the door frame, essentially elongating it in the vertical direction, the x direction.

The semiconductor industry is now moving toward utilizing larger, 450 mm diameter wafers. The larger diameter wafers, although providing cost efficiencies, also provide increased fragility, greater weight, and undiscovered issues associated with handling and storing the larger wafers in containers made of plastic. The flexing and corresponding problems associated with the expanses of plastic on the top, bottom, sides, front, and back are exacerbated.

With the significant leaps in the size of processed wafers, new issues and problems arise that were not present with smaller sized wafers. Many standards for 450 mm wafers, such as the number of wafers in containers and the spacing between wafers, may very well remain the same as 300 mm wafer container standards due to existing equipment compatibilities and cost pressures. And, of course, as wafers get larger in diameter, they correspondingly get heavier. A wafer container that holds the same number of 450 mm wafers as is provided in standardized 300 mm containers is expected to weigh approximately 40 pounds. At this weight, manual handling starts to become more difficult.

Using comparable thicknesses of polymer walls for a larger container may not provide sufficient structural rigidity of the container. That is, the container would be expected to be less dimensionally stable under loading, transfer and shipping due to the greater dimensions and greater expanses of polymer. Thickening the walls and adding significant strengthening structure would further increase the weight of 450 mm wafer containers.

Moreover, conventional 300 mm wafer containers are typically injection molded. It is anticipated that it will be difficult to adequately control the dimensions of larger containers utilizing comparable injection molding practices and comparable or larger wall thicknesses. Currently 300 mm wafer containers generally utilize the shell as the principal structural member for positioning components that interface with wafers and outside equipment, namely the wafer supports and the kinematic coupling machine interface.

In addition, the open interior volume will significantly increase as will the area of the open front that sealingly receives the door. This suggests more difficult sealing issues between the door and the container portion.

Wafers of larger dimensions will also have significantly greater sag which will make them more susceptible to damage during handling and transport and require unique support not required for smaller wafers. This greater sag presents challenges in maintaining the desired spacing between wafers while still allowing placement and removal of the wafers robotically by robotic arms.

Accordingly, it would be desirable to develop front opening configurations for 450 mm wafer containers that have design attributes for minimizing wafer sag and minimizing weight of the container. In addition, configurations providing improved sealing characteristics for the doors would be desirable. Moreover, configurations providing enhanced wafer support to accommodate storing of 450 mm wafers in wafer containers as well during robotic handling of the wafers would be desirable.

### SUMMARY OF THE INVENTION

A front opening wafer container suitable for 450 mm wafers utilizes a wafer cushion on the front door with varying inclinations on the inside surface of a lower leg of V-shaped wafer cushion engagement portions on the door. This arrangement provides enhanced performance. More specifically, in an embodiment of the invention, a front opening wafer container has, in cross section, horizontal V-shaped groove with the inside surface of the lower leg of the V having with at least two surface portions with different inclinations from horizontal. The surface portion adjacent the apex, where the edge of the wafer seats, having a lesser inclination from horizontal than a surface portion more distal from apex.

An issue heretobefore unrecognized is that the weight of the wafers engaged with the cushion on the front door can cause a considerable force component in the z direction thus an outward flexing of the door. In the typical configuration where the edge of the wafer is seated in a V-shaped (rotated 90 degrees) groove. The engagement of the wafer on the lower leg of the V provides a force in a direction normal to the inclination angle of the lower leg. Such force has a component that extends horizontally, in the z direction, that causes considerable force pushing the door outward. It is believed that this force can cause door deflection issues as well as putting excess load on the latches, creating latching difficulties. By reducing the angle of inclination of the lower leg of the V where the edge of the wafer seats, the force component in the z direction can be reduced.

A further and associated advantage and feature of the invention is that the lesser angle of inclination from horizontal of the proximate portion of the lower leg where the wafer seats provides an enhanced capture of the wafer edge reducing the likelihood of the wafer coming disengaged from the wafer cushion under shock load or other transport events. A further feature and advantage of embodiments of the invention is that the pressure required to maintain the capture of the wafer edge in the V-shaped groove and the retention of the wafer edge seated at the apex is less that a V-shaped groove that has a lower leg surface with a greater inclination.

In an embodiment of the invention, a front opening wafer container, suitable for holding large diameter wafers, such as 450 mm wafers, utilizes a front door with wafer cushions having a plurality of V-shaped grooves. The lower leg of the V-shaped groove upon which the edge of the wafer rides when the door is inserted into the door frame of the container portion, has at least two wafer edge engagement surfaces, a first surface with a first angle of inclination that facilitates the wafer edge riding up the ramp as the door is inserted, and a second surface with a second angle of inclination when the wafer is seated at the apex of the V-shaped groove that is less than the first.

One embodiment of the invention is directed to a front opening wafer container including a container portion with a front opening and a front door for operable engagement in the front opening of the container portion. The door has a wafer cushion including a plurality of V-shaped wafer engagement portions. Each V-shaped wafer engagement portion contain an upper leg and a lower leg defining a groove that converges to an apex for seating wafers. Further, the lower leg provides a plurality of inwardly directed surface portions of varying inclinations.

Another embodiment of the invention is directed to a wafer cushion for a wafer container. The wafer container includes a plurality of wafer engagement structures providing V-shaped grooves. Each V-shaped groove has an interior portion including an apex defined by a upper leg and a lower leg that converge with one another. The lower leg has a proximal wafer engagement surface and a distal wafer engagement surface with respect to the apex. Further, the proximal wafer engagement surface is disposed at an first acute angle to horizontal that is less than a second acute angle of the distal wafer engagement surface to horizontal.

Other embodiments of the invention include methods for seating a sagging wafer located within a front opening wafer container. The method includes manipulating a wafer container door having an interior face and an exterior face. The interior face contains a wafer cushion including a plurality of V-shaped members each having a lower leg comprised of a proximal surface and a distal surface disposed at different angles with respect to one another. The method also includes aligning the container door within the front opening of the wafer container to place a wafer in the container in contact with the distal surface of the lower leg of the wafer cushion. Finally, the method includes inserting the container door to cause the wafer to ride up the distal surface of the lower leg and onto the proximal surface of the lower leg to a seating position.

### DESCRIPTION OF THE DRAWINGS

FIG. 1 is a perspective view of a front opening wafer container according to the invention.

FIG. 2 is a perspective view illustrating the inside of the door of the wafer container of FIG. 1.

FIG. 3 is a cross sectional view of a wafer cushion engagement portion according to the invention herein.

FIG. 4 is a cross sectional view of a wafer cushion engagement portion according to the invention herein.

FIG. 5 is a cross sectional view of a wafer cushion engagement portion according to the invention herein.

FIG. 6a is a cross sectional view of a wafer cushion engagement portion in a first position according to the invention herein.

FIG. 6b is a cross sectional view of a wafer cushion engagement portion in a second position according to the invention herein.

FIG. 7 is a cross sectional view of a wafer cushion arrangement having a lower leg of small inclination.

FIG. 8 is a cross sectional view of a wafer cushion arrangement having a lower leg of large inclination.

FIG. 9 is a cross sectional view of a wafer cushion engagement portion according to the invention herein.

FIG. 10 is a cross sectional view of a wafer cushion engagement portion illustrating a seating inclination and a lifting inclination according to the invention herein.

FIG. 11 is a cross sectional view of a wafer cushion engagement portion illustrating insertion of a door by a robotic means according to the invention herein.

FIGS. 12a-b are cross sectional views of a sagging wafer position prior to door insertion and a corrected wafer position upon door insertion according to the invention herein.

### DETAILED DESCRIPTION

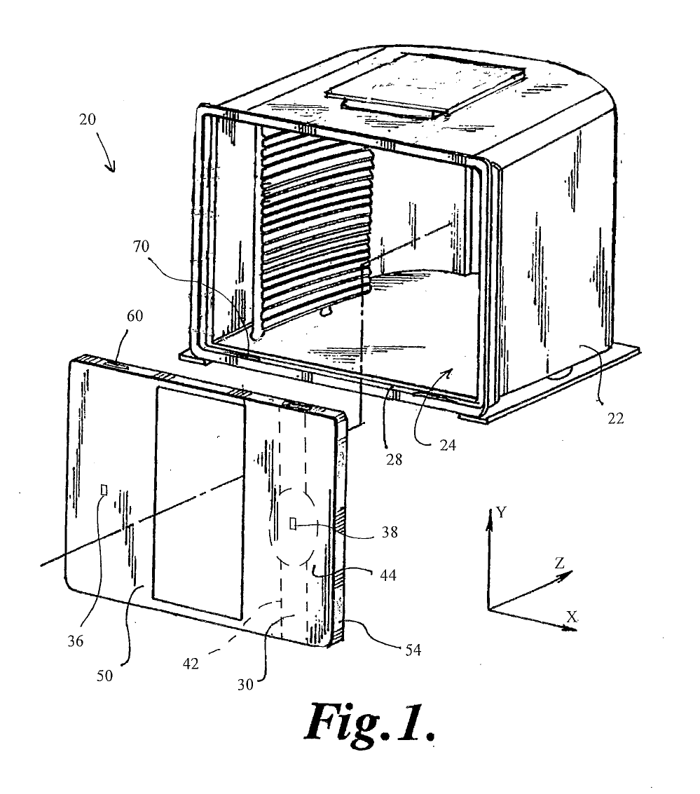

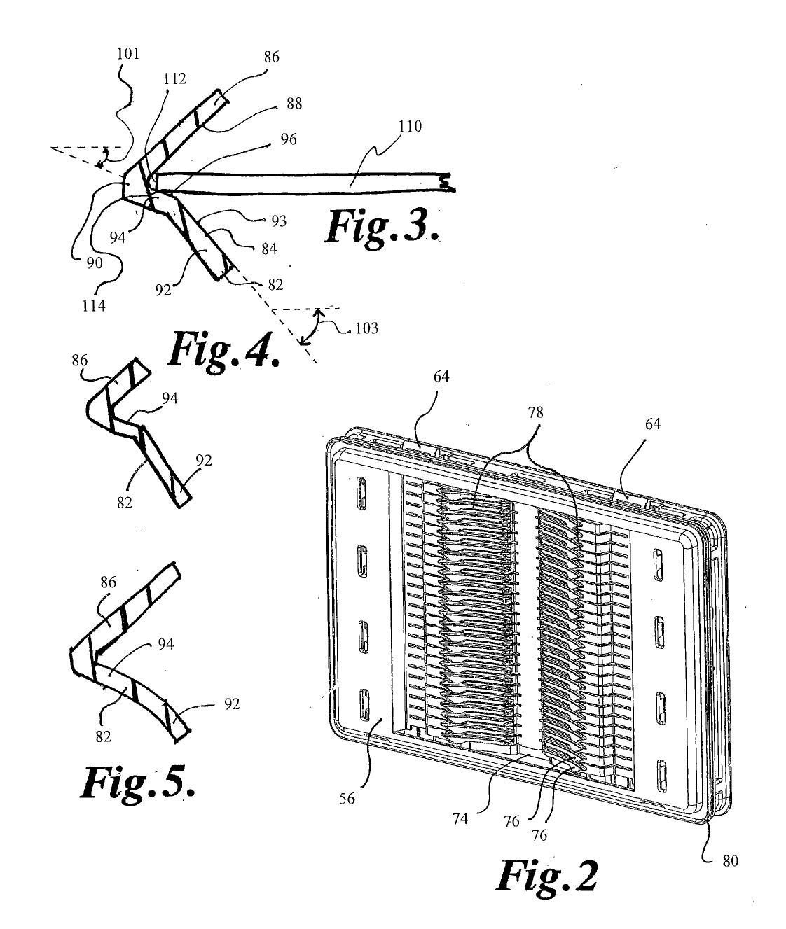

Referring to FIG. 1, a front opening wafer container 20 is illustrated and comprises generally a container portion 22, with a front opening 24 defined by a door frame 28, and a front door 30 configured to close the open front. The door has a pair of key holes 36, 38 that access latch mechanisms 42 located inside the door housing 44. The door has an outside surface 50, a periphery 54, and an inside surface 56. Slots 60 are positioned on the periphery and allow latching tabs 64 or tips to extend and retract from the door to engage and disengage recesses 70 on the inside surface of the door frame.

Centrally positioned on the inside of the door is a recess 74. Positioned in the recess are a plurality of wafer engagement portions 76 positioned for engagement with a vertical stack of spaced wafers positioned in the container portion 22. The door has a seal or gasket 80 that engages and seals with the door frame. The wafer engagement portions 76 comprise a wafer cushion 78 which supports and cushions the wafers when the door is latched onto the container portion.

Referring to FIG. 3, various cross sections of wafer engagement portions 76 are illustrated as well as a 450 mm wafer 110. The wafer engagement portion 76 has a V-shape, rotated 90 degrees and has a lower leg 82 with an inwardly facing lower leg surface 84, an upper leg 86 with an inwardly facing upper leg surface 88. The lower leg has an apex 90, a distal portion 92, with respect to the apex, the distal portion having a inwardly facing distal portion surface 93. The lower leg further having proximal portion 94 with an inwardly facing proximal portion surface 96. The proximal portion surface is positioned at an angle 101 from horizontal and the distal portion surface is positioned at an angle 103 from horizontal with the angle formed by the proximal portion surface being less than the angle formed by the distal portion surface. In other words, the proximal portion. When the wafer 110 engages the door when it is placed in the door frame, the wafer peripheral edge 112, more specifically the lower corner 114, engages the inwardly facing surface 93 of the distal portion of the lower leg and rides up the lower leg to the proximal portion. See U.S. Pat. No. 6,267,245, incorporated by reference, which describes this action and the constraint of the wafer in the container. In this case, the proximal portion provides a near shelf feature that can support the edge of the wafer without as much inward force for retaining the wafer edge therein under shock conditions as would be required in a normal inclined surface such as provided by the distal portion of the lower leg.

Referring to FIG. 4, a different configuration with a lower leg being longer that the upper leg, for example, at least 20% longer, or at least 30% longer in some embodiments, or 40% longer in some embodiments, or 60% longer in some embodiments.

Referring to FIG. 5, a further embodiment is illustrated, with the transition between the distal portion and proximal portion not being definite as in the previous embodiments. Still the angle, either the average angle of the surface of a distal portion to horizontal or an angle at a discrete point on the distal portion to horizontal is greater than the average angle to horizontal or an angle to horizontal of a discrete point on the proximal portion.

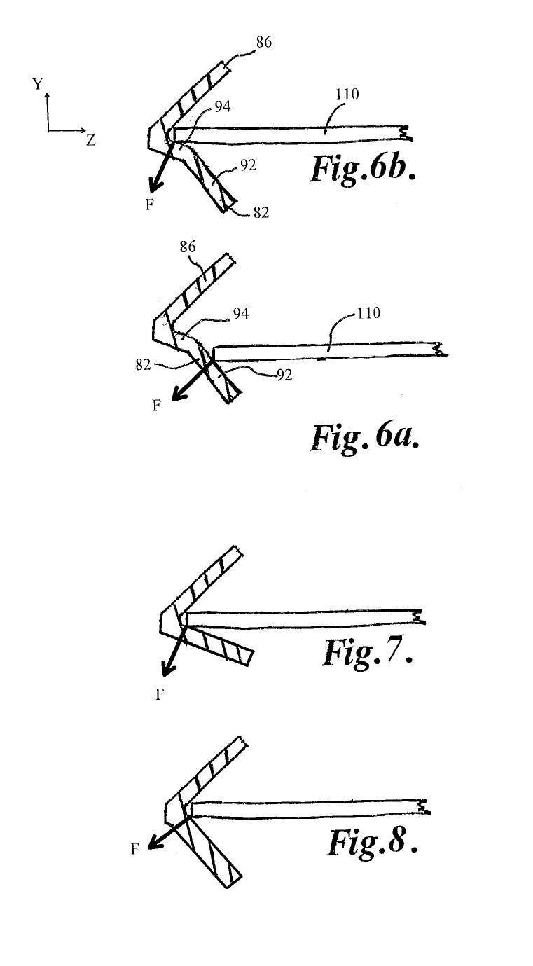

FIGS. 6a and 6b illustrate the engagement of a 450 mm wafer 110 with alternate portions of the lower leg 82. Specifically, FIG. 6a depicts the wafer 110 in contact with the distal portion 92 of the lower leg of the cushion 78 and FIG. 6b depicts the wafer 110 in contact with the proximal portion 94 of the lower leg of the cushion 78. Accordingly, the operation to seat a large, potentially sagging, wafer with a wafer cushion can be better understood from the following discussion and referenced figures.

Final seating of wafers that are loaded into a front opening wafer container to correct for sagging, include several steps. These include manipulating a wafer container door having an interior face and an exterior face where the interior face contains a wafer cushion with a plurality of V-shaped members as described in embodiments throughout this application. Specifically, each of the V-shaped members have a lower leg 82 comprised of a proximal surface 96 and a distal surface 93 disposed at different angles with respect to one another. Operation requires aligning the container door 30 within the front opening 24 of the wafer container 20 to place a wafer 110 in the container in contact with the distal surface 93 of the lower leg 82 of the wafer cushion 78. At this point, the wafer should be in a configuration similar to the one seen in FIG. 6a. The lower leg 82 is designed such that it extends down far enough to readily engage a wafer 110 deflected or sagging downward from its desired height for retention during shipping and storage. The steep angle of the distal surface 93 of the leg is beneficial in terms of its dimensions slim dimensions relative to the door and allows for an elongated area of contact for a deflected wafer. In some embodiments, the angle of the distal surface from horizontal is an acute angle less than 50 degrees. In some embodiments the angle is between about 45 and 50 degrees.

The next step in seating the wafers requires inserting the container door 30 to cause the wafer 110 to ride up the distal surface 93 of the lower leg and onto the proximal surface 96 of the lower leg to a seating position. Once the wafer is on the proximal surface and portion of the lower leg 82, it is further urged into the apex of the V-shaped groove for retention and storage. The resulting wafer configuration is seen in FIG. 6b. The angle 101 of the proximal surface 96 to horizontal is less than the angle 103 of the distal surface to horizontal. In some embodiments, this acute angle 101 is less than 30 degrees. In some embodiments, this angle 101 is about 30 degrees. This angle and apex seating arrangement is beneficial because it provides for enhanced shock protection and wafer retention and resistance to bending and deflection under shock load and transport.

Force vectors have been added to FIGS. 6a and 6b to further depict the advantageous nature of the multi-surface arrangement provided for by embodiments of this invention. One of the reasons for the multi-angled design is due to the considerable weight of the wafers engaged with the cushion on the front door, especially with respect to the new larger, and heavier 450 mm diameter designs. This weight can cause significant forces against the door 30 and result in outward flexing of the door 30. For a statics standpoint, when the edge of the wafer 110 is engaged on the lower leg 82 of the V shaped engagement structure, a force (F) is exerted in a direction normal to the inclination angle of the lower leg, as shown in FIG. 6a. This force has a horizontal component that extends in the z direction against the door, that results in considerable force being placed on the door, potentially pushing the door outward. This outward force can result in a variety of issues resulting from door deflection. Moreover, such a load may be partially transferred to the latches 64, potentially causing further latch-related problems. By reducing the angle of inclination on the proximal portion of the lower leg 82, where the edge of the wafer 110 seats, the force component in the z direction is reduced. Further, the reduced angle of inclination better utilizes friction to prevent movement. Accordingly, the resting location on the proximal portion 94 of the lower leg 82 provides a better arrangement for shock retention and is more resistant to bending and deflection under load conditions.

FIGS. 7 and 8 are included to illustrate the how various cushion cross sections having a single surface angle on its lower surface will not provide the benefits of the two surface arrangement of the lower leg of the wafer engagement portions of the cushion. FIG. 7 shows a lower leg having a single surface inclination. This inclination to horizontal is relatively small. In this case, the lower leg cannot provide a large vertical contact area to initially engage the wafer. Some wafers may have sufficient deflection such that contact can not be easily made under such conditions. Extending the leg further at this angle will result in a significant and undesirable length of projection from the door wall. Such an extended projection is not desirable for automation reasons as well as structural reasons. FIG. 8 shows an alternative lower leg having a single surface inclination where the inclination to horizontal is relatively large. In such a case, the lower leg requires significant force to engage and retain the wafer and may result in considerable forces being exerted on the door as discussed above. Contrary to FIGS. 7 and 8, embodiments of the present invention provide for multiple angles which provides the benefits of having both angles without the problematic drawbacks discussed here.

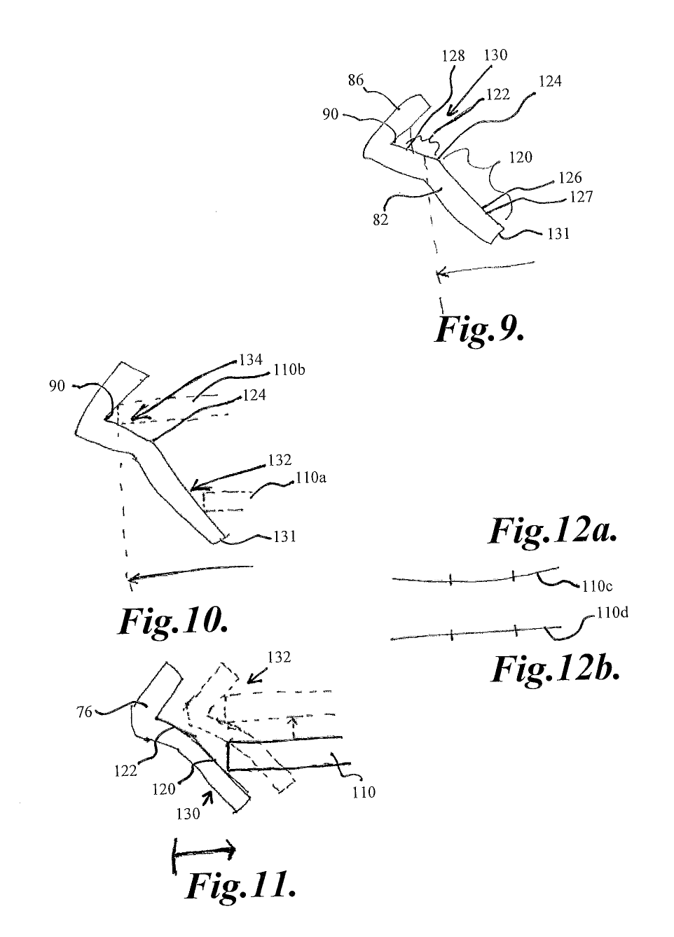

FIG. 9 shows a cross sectional view of a wafer cushion engagement portion. The wafer cushion 78, as illustrated, includes a lower leg 82 with both a higher inclination surface 120 as well as an adjacent lower inclination surface 122. The higher inclination surface 120 is generally distal to the groove apex 90, where the upper and lower leg portions meet. The lower inclination surface 122 is proximal the apex 90. Both surfaces 120 and 122 are relatively flat and uniform. These surfaces join one another at a lower leg apex 124 located where the higher inclination surface 120 and lower inclination surface 122 meet. The higher inclination surface 120 is generally considered a lifting surface 126, as its primary purpose is to serve as a ramp 127 to the upper inclination surface 122. The upper inclination surface 122 can also be referred to as the seating surface 128 as this surface of lesser slope is the location at which wafers 110 are intended to reside in a fully closed wafer container. Also, the entire region in which the lower inclination surface 122 and the upper leg 86 form a groove is generally referred to as the seating portion 130. The margins of the lower inclination surface 122 defined by the groove apex 90 and the lower leg apex 124. The margins of the higher inclination surface 120 are defined by the apex 124 and the end 131 of the lower leg 82. The end 131 is also referred to as the margin 131 of the lower leg 82.

FIG. 10 is a cross sectional view of a wafer cushion engagement portion illustrating a seating inclination and a lifting inclination. In general, a wafer 110a is shown on the lifting inclination 132 and a wafer 110b is shown on the seating inclination 134. In general, the seating inclination 134 corresponds to the seating surface 128 and the lifting inclination 132 corresponds to the lifting surface 126. The seating portion and a lifting portion are divided by an apex 124, the apex 124 on the lower leg 82 intermediate the groove apex 90 and the margin of the lower leg of the V, the apex 124 facing inwardly toward the interior of the enclosure portion away from the door.

FIG. 11 is a cross sectional view of a wafer cushion engagement portion illustrating insertion of a door by a robotic means. When the door is horizontally inserted into the door frame by a load port, wafers 110 horizontally stacked in the corresponding wafer container are generally raised up into a seating position in which wafer sag is reduced. This is accomplished by use of the wafer cushion 78 and wafer engagement portions secured to the door. When the door is initially inserted in the door frame of the container, the wafers first contact the lifting surfaces 120 of the cushions, as shown at wafer position 130. As the door and wafer engagement portion 76 is inserted further, the wafer rides up the lifting surface 120 until it reaches the seating surface 122 at wafer position 132. When the wafer 110 reaches this point, sagging is largely reduced and the wafer is retained in a secure position so that the containers can be readily manipulated or stored.

FIGS. 12a-b illustrate this wafer loading concept as well. These figures are respectively, a cross sectional view of a sagging wafer 110c prior to door insertion in FIG. 12a, and a cross sectional view of a corrected wafer 110d as positioned upon door insertion and wafer raising by the cushion 78 in FIG. 12b.

In many front opening containers, particularly those used for shipping, the insertion of the front door into the door frame utilizes the ramps on the V grooves in the wafer cushion on the front door and ramps on V grooves at the rear of the container to elevate the wafer off the shelves as the door is being shut and sealed. This is likely to be adopted in the 450 mm arena. This type of arrangement is discussed in detail in U.S. Pat. No. 6,267,245 and is hereby incorporated by reference.

Please note that the various configurations discussed could also be used on the wafer engagement portions on the rear of the enclosure portion, which may or may not be cushions. For example, these structures may be rigid polymer seating portions that are part of the shelves.

It should also be appreciated that the exemplary embodiment or exemplary embodiments are only examples, and are not intended to limit the scope, applicability, or configuration of the invention in any way. Rather, the foregoing detailed description will provide those skilled in the art with an enabling disclosure for implementing the exemplary embodiment or exemplary embodiments. It should be understood that various changes can be made in the function and arrangement of elements without departing from the scope of the invention as set forth in the appended claims and the legal equivalents thereof.

The embodiments above are intended to be illustrative and not limiting. Additional embodiments are within the claims. Although the present invention has been described with reference to particular embodiments, workers skilled in the art will recognize that changes may be made in form and detail without departing from the spirit and scope of the invention.

Various modifications to the invention may be apparent to one of skill in the art upon reading this disclosure. For example, persons of ordinary skill in the relevant art will recognize that the various features described for the different embodiments of the invention can be suitably combined, un-combined, and re-combined with other features, alone, or in different combinations, within the spirit of the invention. Likewise, the various features described above should all be regarded as example embodiments, rather than limitations to the scope or spirit of the invention. Therefore, the above is not contemplated to limit the scope of the present invention.

1. A front opening wafer container comprising:
a container portion with a front opening; and
a front door for operable engagement in the front opening of the container portion having a wafer cushion including a plurality of V-shaped wafer engagement portions, each V-shaped wafer engagement portion containing an upper leg and a lower leg defining a groove that converges to an apex for seating wafers, the lower leg providing a plurality of inwardly directed surface portions of varying inclinations, the upper leg having a single inwardly directed surface portion of a single inclination, a length of the surface portion from the apex being less than a length of the plurality of inwardly surface portions of varying inclinations of the lower leg.

2. The front opening wafer container of claim 1, wherein the plurality of inwardly directed surface portions include a first surface portion proximal the apex and a second surface portion distal the apex, the first surface portion disposed at a lesser angle of inclination from horizontal than the second surface portion.

3. The front opening wafer container of claim 2, wherein the angle of inclination of the first surface portion relative to horizontal is 30 degrees or less.

4. The front opening wafer container of claim 3, wherein the second angle of inclination of the first surface portion relative to horizontal is less than 50 degrees.

5. (canceled)

6. The front opening wafer container of claim 2, wherein the wafer container is sized to support 450 mm diameter wafers.

7. The front opening wafer container of claim 2, wherein the lower leg is at least 20% longer than the upper leg when measured from the apex.

8-10. (canceled)

11. The front opening wafer container of claim 1, wherein the plurality of inwardly directed surface portions of varying inclinations generally having a distal portion and a proximal portion with respect to the apex, the distal portion and proximal portion having an indefinite transition location and define an average surface angle of the distal portion to horizontal which is greater than an average surface angle of the proximal portion to horizontal.

12. The front opening wafer container of claim 1, wherein the plurality of inwardly directed surface portions of varying inclinations generally having a distal portion and a proximal portion with respect to the apex, the distal portion and proximal portion having an indefinite transition location and define an surface angle at a discrete point on the distal portion to horizontal that is greater than a surface angle at a discrete point on the proximal portion to horizontal.

13. A wafer cushion for a wafer container, comprising:
a plurality of wafer engagement structures providing V-shaped grooves, each V-shaped groove having an interior portion including an apex defined by a upper leg and a lower leg that converge with one another, the lower leg having a proximal wafer engagement surface and a distal wafer engagement surface with respect to the apex, the proximal wafer engagement surface disposed at an first acute angle to horizontal that is less than a second acute angle of the distal wafer engagement surface to horizontal, the upper leg consisting of an inwardly facing surface of a single angle to horizontal.

14. The wafer cushion of claim 13, wherein the first acute angle is 30 degrees or less.

15. The wafer cushion of claim 14, wherein the second acute angle is less than 50 degrees.

16. (canceled)

17. The wafer cushion of claim 13, wherein the front opening wafer container and the wafer cushion is sized to support 450 mm diameter wafers.

18. The wafer cushion of claim 13, wherein the lower leg is at least 20% longer than the upper leg in the cross-section measured from the apex.

19-21. (canceled)

22. The wafer cushion of claim 13, wherein the proximal wafer engagement surface and the distal wafer engagement surface converge at an indefinite transition.

23. A method of seating a sagging wafer located within a front opening wafer container, comprising:
manipulating a wafer container door having an interior face and an exterior face, the interior face containing a wafer cushion including a plurality of V-shaped members each having a lower leg comprised of a proximal surface and a distal surfaces disposed at different angles with respect to one another and an upper leg shorter than the lower leg;
aligning the container door within the front opening of the wafer container to place a wafer in the container in contact with the distal surface of the lower leg of the wafer cushion; and
inserting the container door to cause the wafer to ride up the distal surface of the lower leg and onto the proximal surface of the lower leg to a seating position.

24. The method of seating of claim 23 further comprising loading a 450 mm diameter wafer in the container.

25. The method of seating of claim 23 wherein, the proximal surface of the lower leg has a lesser angle with respect to horizontal than the distal surface of the lower leg with respect to the horizontal.

26. The method of seating of claim 23 wherein, the proximal surface of the lower leg has less than a 30 degree angle with respect to horizontal.

27. The method of seating of claim 24 wherein, the distal surface of the lower leg has less than a 50 degree angle with respect to horizontal.

28. The method of seating of claim 24 wherein, the distal surface of the lower leg has an angle with respect to horizontal of between 45 to 50 degrees.
